(19) United States
(12) Patent Application Publication
(10) Pub. No.: US 2018/0226534 A1
(43) Pub. Date: Aug. 9, 2018

(54) METHOD FOR PRODUCING A NITRIDE SEMICONDUCTOR COMPONENT, AND NITRIDE SEMICONDUCTOR COMPONENT

(71) Applicant: OSRAM Opto Semiconductors GmbH, Regensburg (DE)

(72) Inventors: Tobias MEYER, Regensburg (DE); Christian LEIRER, Friedberg (DE)

(21) Appl. No.: 15/750,139

(22) PCT Filed: Jul. 29, 2016
(86) PCT No.: PCT/EP2016/068166

§ 371 Date: Feb. 2, 2018

(30) Foreign Application Priority Data
Aug. 6, 2015 (DE) 10 2015 112 944.2

(51) Int. Cl. H01L 33/00; H01L 33/32; H01L 33/22

(52) U.S. Cl. CPC H01L 33/007; H01L 33/22; H01L 33/32

(57) ABSTRACT

The invention relates to a method for producing a nitride semiconductor component (10), comprising the following steps: epitaxially growing a nitride semiconductor layer sequence (2) on a growth substrate (1), wherein recesses (7) are formed on a boundary surface (5A) of a semiconductor layer (5) of the semiconductor layer sequence (2), growing a p-doped contact layer (8) over the semiconductor layer (5), wherein the p-doped contact layer (8) at least partially fills the recesses, and wherein the p-doped contact layer (8) has a lower dopant concentration in first regions (81) arranged at least partially in the recesses (7) than in second regions (82) arranged outside of the recesses (7), and applying a connection layer (9), which has a metal, a metal alloy, or a transparent conductive oxide, to the p-doped contact layer (8). The invention further relates to a nitride semiconductor component (10) that can be produced by means of the method.

The invention relates to a method for producing a nitride semiconductor component, and to a nitride semiconductor component, in particular an optoelectronic nitride semiconductor component such as a light-emitting diode or a semiconductor laser.

This patent application claims priority from German patent application 10 2015 112 944.2, the disclosure content of which is hereby incorporated by reference.

The semiconductor layer sequence of a nitride semiconductor component is usually grown on a growth substrate that is lattice-mismatched with respect to the nitride semiconductor material, i.e. the lattice constants of the growth substrate and of the nitride semiconductor material do not match. Such a growth substrate is sapphire, for example. Because of the different lattice constants, mechanical stresses will develop in the semiconductor material, which stresses may lead to crystal defects such as dislocations. One type of dislocateions occurring in the semiconductor material are threading dislocations, part of which propagate in the growth direction of the semiconductor layers and thus extend essentially perpendicularly to the growth substrate.

Dislocations present in the semiconductor layer sequence may reduce the efficiency of a semiconductor component. For example, in a radiation-emitting optoelectronic component, non-radiating recombinations of charge carriers may increasingly occur in the area of dislocations, thus reducing the radiation yield.

One object to be achieved is to provide an improved method for producing a nitride semiconductor component, and a nitride semiconductor component that is characterized by improved efficiency, in particular a higher radiation yield.

This object is achieved by a method for producing a nitride semiconductor component, and by a nitride semiconductor component as specified in the independent claims.

In at least one embodiment, the method for producing a nitride semiconductor component provides for a nitride semiconductor layer sequence to be epitaxially grown on a growth substrate, in particular by metal organic vapor phase epitaxy (MOVPE).

In the present context, the term “nitride semiconductor layer sequence” means that the semiconductor layer sequence, or at least one layer thereof, comprises a III-nitride compound semiconductor material, preferably InₓAl_{y}Ga_{1-x-y}N, with 0≤x≤1, 0≤y≤1 and x+y≤1. However, such material does not necessarily have to be of a mathematically exact composition according to the above formula. Rather, it can include one or plural dopants as well as additional components which essentially do not change the characteristic physical properties of the InₓAl_{y}Ga_{1-x-y}N material. For reasons of simplicity, however, the above formula only contains the essential components of the crystal lattice (In, Al, Ga, N), even if these can be partially replaced by small amounts of other substances.

The nitride semiconductor layer sequence is in particular grown on a growth substrate having a lattice constant that differs from the lattice constant of the semiconductor material. For example, the growth substrate can be a sapphire substrate. Alternatively, the growth substrate can include Si or SiC, for example.

Because of a lattice mismatch between the growth substrate and the nitride semiconductor layer sequence, crystal defects may occur in the semiconductor layer sequence. In particular, threading dislocations may form in the semiconductor layer sequence.

GaN, AlN or another III-N-material can also be used as a growth substrate. The deposited semiconductor layer sequence can grow thereon in a lattice-matched manner (i.e. with the same lattice constant), with the result that there will be no or only few threading dislocations. However, threading dislocations may already be present in the substrates and then propagate through the semiconductor layers deposited on the substrates.

Some of the threading dislocations typically propagate vertically in the semiconductor layer sequence, i.e. essentially in parallel to the direction of growth. At those points of a boundary surface of one semiconductor layer of the semiconductor layer sequence where threading dislocations meet the boundary surface, recesses may form which are essentially V-shaped. “V-shaped” refers to the appearance of the recesses as seen in cross-section. The V-shaped recesses may in particular take the form of inverted pyramids, as viewed in the growth direction of the semiconductor layer sequence, which inverted pyramids have a hexagonal base, for example.

More specifically, the recesses can be created in that in the immediate vicinity of the threading dislocations, the semiconductor material does not grow in the c-direction, as usual, i.e. in the (0001) crystal direction, but grows obliquely to the c direction. In particular, the V-shaped recesses can have side facets that are constituted by a (1-101) crystal face or an (11-22) crystal face.

In at least one embodiment of the method, in a further step thereof, a p-doped contact layer is grown on the semiconductor layer having the recesses. The p-doped contact layer, same as the layers of the semiconductor layer sequence arranged underneath it, is advantageously formed from a nitride semiconductor material, in particular from InₓAl_{y}Ga_{1-x-y}N, with 0≤x≤1, 0≤y≤1 and x+y≤1. The p-doped contact layer includes at least one p-dopant, preferably magnesium. More specifically, the p-doped contact layer can be the outermost semiconductor layer on the p-side of the nitride semiconductor component. It is also possible for the p-doped contact layer to comprise several partial layers that differ in material composition, dopant and/or dopant concentration, for example.

The p-doped contact layer fills the recesses at least partially or preferably completely. After the growth step, the p-doped contact layer preferably has a lower dopant concentration in first regions arranged at least partially in the recesses than in second regions arranged outside of the recesses.

In particular, the different dopant concentrations in the first and second regions can be produced by incorporating a lower concentration of the p-dopant, such as magnesium, in the first regions in which the nitride semiconductor material grows on the recesses whose crystal faces extend obliquely relative to the growth direction than in the second regions in which the nitride semiconductor material grows in the c direction. As a result, the nitride semiconductor material has a lower dopant concentration in the first regions, in which threading dislocations extend in the semiconductor layer sequence, than in the second regions.

In at least one embodiment of the method, in another step thereof, a connection layer preferably having a metal, a metal alloy or a transparent conductive oxide is applied to the p-doped contact layer. The connection layer preferably directly adjoins the p-doped contact layer. The connection layer serves to electrically contact the p-side of the nitride semiconductor component.

Because the p-doped contact layer has a lower dopant concentration in the first regions than in the second regions, the contact resistance between the connection layer and the p-doped contact layer is not constant in the lateral direction, but is higher in the first regions than in the second regions. This advantageously results in less current being impressed into the regions of the semiconductor layer sequence that adjoin the recesses than into the regions that do not adjoin the recesses. The current flow through the nitride semiconductor component will thus advantageously be reduced in those regions in which there are threading dislocations. Rather, the current flow will increasingly concentrate in those regions in which there are no threading dislocations. This advantageously improves the efficiency of the nitride semiconductor component.

In at least one advantageous embodiment, the dopant concentration in the p-doped contact layer varies at a boundary surface to the connection layer in the lateral direction, i.e. in a direction parallel to the layer plane. In particular, the dopant concentration is lower in regions of the p-doped contact layer that are arranged above the recesses at the boundary surface to the connection layer than in regions which are arranged next to the recesses in the lateral direction. In other words, the reduced dopant concentration in the first regions of the p-doped semiconductor layer propagates up to the boundary surface between the p-doped contact layer and the connection layer, as seen in the vertical direction.

This can be achieved firstly by interrupting the growth of the p-doped contact layer before a dopant concentration that is constant in the lateral direction is reached at a growth surface. After the recesses have been grown over by the p-doped contact layer, growth above the recesses will increaseingly proceed in the c-direction, resulting in the incorporation of dopant into the p-doped contact layer evening out in the lateral direction with increased growth rate. To ensure that there is still a dopant concentration that varies in the lateral direction at the boundary surface between the p-doped contact layer and the connection layer, the growth of the p-doped contact layer is interrupted before the incorporation of dopant evens out in the lateral direction. For the ratio of a thickness a of the p-contact layer to the averaged lateral extent b of the recesses, the following relationship shall be satisfied: advantageously a≤2*b, preferably a≤1.5*b, more preferably a≤0.5*b. Because the lateral extents of the recesses can vary, b is the lateral extent averaged over all recesses. Preferably, the thickness a of the p-doped contact layer is not more than 300 nm. This effectively reduces the current flow through the regions of the semiconductor layer sequence that are affected by dislocateions.

An alternative option for achieving a dopant concentration that varies in the lateral direction at the boundary surface between the p-doped semiconductor layer and the connection layer is to remove the p-doped contact layer partially after the growth step. More specifically, an etching process can remove the p-doped contact layer partially. In particular, the p-doped contact layer is removed to such an extent that the dopant concentration in the p-doped contact layer varies in the lateral direction at the surface in such a way that it is lower in regions above the recesses than in regions arranged next to the recesses in the lateral direction.

In another advantageous embodiment of the process, an etching step is performed before applying the p-doped contact layer, which etching step is used to produce and/or enlarge the recesses. It is possible that recesses already exist at the boundary surface of the semiconductor layer after the epitaxial growth, with threading dislocations terminating at these recesses. However, these recesses, which are at least partially created at the ends of threading dislocations through a self-organization process, may not be large enough to provide sufficient lateral variation in the dopant concentration in the p-doped contact layer. In this case, it is considered advantageous to enlarge the recesses by means of an etching process.

In a preferred embodiment, at least some of the recesses at the boundary layer between the semiconductor layer and the p-doped contact layer have a width of at least 10 nm, more preferably of between 15 nm and 500 nm, and most preferably of between 20 nm and 300 nm. Preferably, the depth of the recesses is at least partially 10 nm, more preferably between 15 nm and 500 nm, and most preferably between 20 nm and 500 nm.

In an embodiment, the dopant concentration in the second regions of the p-doped contact layer is at least 5*10¹⁹ cm⁻³, preferably at least 1*10²⁰ cm⁻³, and more preferably 2*10²⁰ cm⁻³. In the second regions, the dopant concentration is preferably at least 1.5 times as high as in the first regions. This allows an efficient reduction of the current flow through those regions of the semiconductor layer sequence in which there are threading dislocations. Furthermore, the dopant concentration in the first regions is advantageously at least partially lower than 1*10²⁰ cm⁻³, preferably lower than 5*10¹⁹ cm⁻³.

In at least one embodiment, the p-doped contact layer has a first partial layer which contains the first and second regions, and a second partial layer which latter has a higher dopant concentration than the first partial layer in its first and second regions. In this case, the second partial layer with the higher dopant concentration advantageously has a thickness of c≤50 nm, preferably of c≤30 nm, and more preferably of c≤15 nm.

This embodiment is based on the insight that an important factor for the contact resistance between the p-doped contact layer and a subsequent connection layer, which contains a metal or a conductive oxide, for example, is not only the doping concentration at the intermediate boundary layer but also the doping concentration within a certain region of the p-doped contact layer. This region can be up to approx. 30 nm in thickness. In particular, the contact resistance between the p-doped contact layer and the subsequent connection layer is determined by the uppermost 30 nm of the p-doped contact layer. As long as the thickness c of the second partial layer is not too high, i.e. c≤50 nm, preferably c≤30 nm, more preferably c≤15 nm, the contact resistance is higher in the area above the recesses than in other areas that are located between the recesses. This thus reduces the current flow in the area of the recesses.

In yet another advantageous embodiment, before growing the p-doped contact layer, another semiconductor layer is grown on the semiconductor layer having the recesses, which additional semiconductor layer has a lower dopant concentration than the second regions of the p-doped contact layer. Preferably, the dopant concentration in the additional semiconductor layer is lower than 1*10²⁰/cm³, more preferably lower than 8*10¹⁹/cm³, most preferably lower than 6*10¹⁹/cm³. Similar to the p-doped contact layer which has first regions with a lower doping concentration in the area of the recesses and second regions with a higher doping concentration, the additional semiconductor layer can have first regions with a lower doping concentration in the area of the recesses and second regions with a higher doping concentration.

This embodiment makes use of the knowledge, amongst others, that the p-conductivity in the nitride compound semiconductor system does not rise monotonically with increasing dopant content but rather decreases again from approx. 4*10¹⁹/cm³ onwards. For example, a layer having a dopant concentration of 1*10²⁰/cm³ can have a poorer p-conductivity than a layer having a dopant concentration of 4*10¹⁹/cm³. However, this correlation is not true for the contact resistance. The contact resistance decreases with increasing dopant concentration, even if the dopant concentration is more than 4*10¹⁹/cm³.

As a result, the highly doped second regions of the p-doped contact layer can have a low contact resistance but poor conductivity, whereas the first regions with the lower doping concentration can have a high contact resistance but good conductivity. The second regions have a higher doping concentration than the first regions, with the result that the contact resistance R is lower in the second regions and hence this is where current preferably flows. The second regions of the additional semiconductor layer have a higher doping concentration than the first regions of the additional semiconductor layer and thus higher conductivity; with the result that current preferably flows in the second partial regions of the additional semiconductor layer. This advantageously reduces the current flow in the area of the recesses, i.e. in the area of threading dislocations.

In a preferred embodiment, the additional semiconductor layer, which is arranged between the semiconductor layer with the recesses and the p-doped contact layer, has a thickness d which satisfies the following relationship with respect to the mean depth e of the recesses: d>0.1*e, preferably d>0.25*e, more preferably d>0.5*e. It therefore follows from this geometrical relationship between the additional semiconductor layer of relatively good conductivity and the depth of the recesses that current increasingly flows from the second partial regions of the p-doped contact layer to the additional semiconductor layer, instead of from the second partial regions to the first partial regions of the p-doped contact layer. This keeps charge carriers away from the dislocations and thus reduces losses.

The nitride semiconductor component that can be produced with the method comprises a nitride semiconductor layer sequence, in which recesses are formed at a boundary surface of a semiconductor layer of the semiconductor layer sequence. The nitride semiconductor component furthermore advantageously comprises a p-doped contact layer that follows the semiconductor layer that has the recesses formed therein and at least partially fills the recesses. The p-doped contact layer has a lower dopant concentration in first regions that are arranged at least partially in the recesses, than in second regions that are arranged outside the recesses. The nitride semiconductor component further comprises a connection layer that includes a metal, a metal alloy or a transparent conductive oxide or consists of such, which connection layer follows the p-doped contact layer and preferably directly adjoins the p-doped contact layer.

Additional advantageous embodiments of the nitride semiconductor component can be gathered from the description of the method, and vice versa.

The nitride semiconductor component can in particular be an optoelectronic semiconductor component, for example a light-emitting diode or a semiconductor laser. The nitride semiconductor layer sequence preferably has an n-type semiconductor region, a p-type semiconductor region, and an active layer arranged between the n-type semiconductor region and the p-type semiconductor region. More specifically, the active layer can be a radiation-emitting active layer. The active layer can be formed as a pn junction, as a double heterostructure, as a single or multiple quantum well structure, for example. The term quantum well structure comprises any structure in which confinement of the charge carriers results in a quantization of their energy states. More specifically, the term quantum well structure does not contain any indication as to the dimensionality of the quantization. It thus comprises quantum wells, quantum wires and quantum dots, as well as any combination of these structures.

Decreased current injection into the regions of the semiconductor layer sequence which have threading dislocations advantageously results in the reduction of non-radiating recombinations of charge carriers in the area of the threading dislocations. This increases the radiation yield and thus the efficiency of the optoelectronic component.

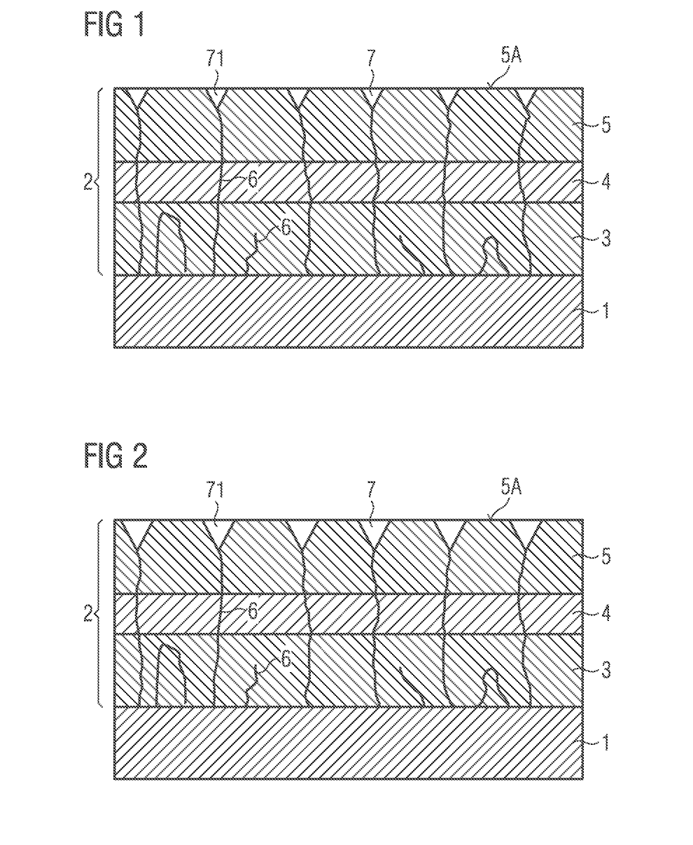

The invention will be explained in more detail in the following text in which reference is made to FIG. 1 through 13.

In the drawings,

FIGS. 1, 2 and 6 are schematic views of intermediate steps in an embodiment of the method,

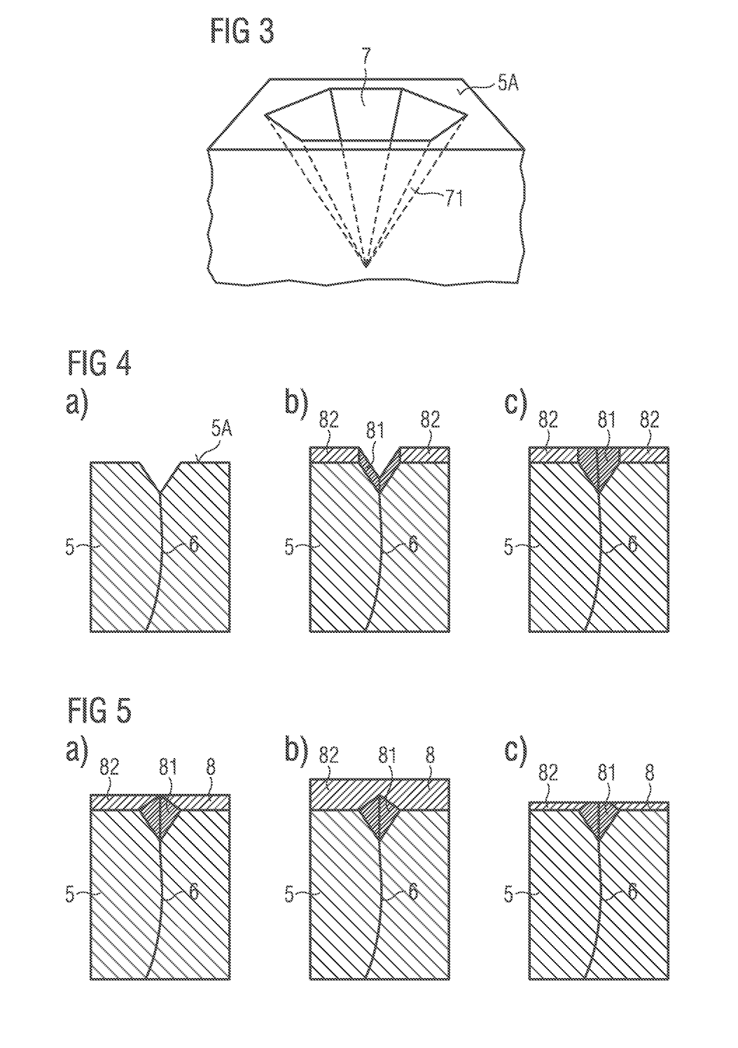

FIG. 3 is a schematic perspective view of a recess,

FIGS. 4a to 4c are schematic views of intermediate steps in the deposition of the p-doped contact layer in an embodiment of the method,

FIGS. 5a to 5c are schematic views of intermediate steps in the deposition of the p-doped contact layer in another embodiment of the method,

FIG. 7 is a schematic cross-sectional view through an embodiment of a nitride semiconductor component,

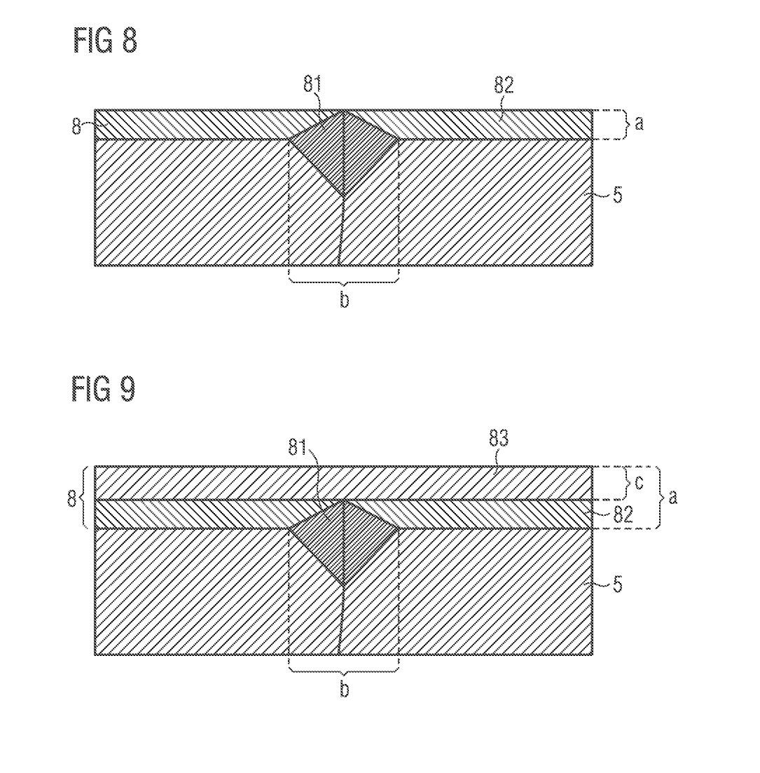

FIGS. 8 to 10 are schematic views each of a portion of the p-doped contact layer of further embodiments,

FIG. 11 is a schematic graph of the contact resistance R and the conductivity σ as a function of the dopant concentration in an embodiment,

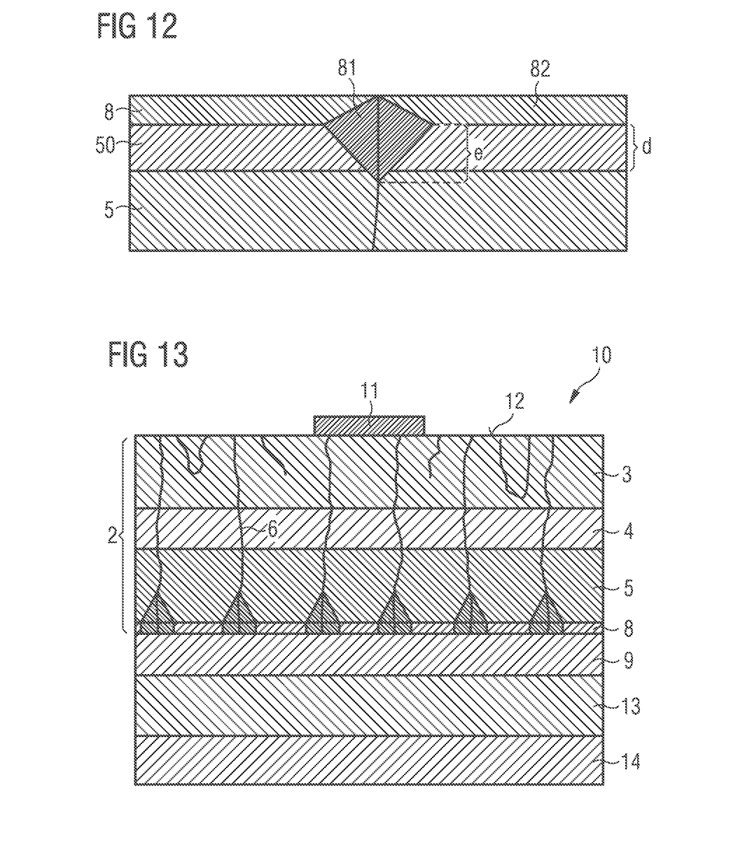

FIG. 12 is a schematic view of a portion of the p-doped contact layer in another embodiment,

FIG. 13 is a schematic cross-sectional view through another embodiment of a nitride semiconductor component.

In the Figures, identical or identically acting components are in each case designated with the same reference numbers. The components illustrated and the size ratios of the components to one another should not be regarded as to scale.

In the intermediate step, as illustrated in FIG. 1, of an embodiment of the method for producing a nitride semiconductor component, a nitride semiconductor layer sequence 2 has been grown on a growth substrate 1. More specifically, the semiconductor layer sequence 2 is grown epitaxially on the growth substrate 1, for example using MOVPE. The growth substrate 1 for example comprises sapphire, GaN, Si or SiC.

The semiconductor layer sequence 2 contains an n-type semiconductor region having at least an n-doped semiconductor layer 3, a p-type semiconductor region having at least one p-doped semiconductor layer 5, and an active layer 4 which is arranged between the n-type semiconductor region and the p-type semiconductor region. The n-type semiconductor region and the p-type semiconductor region can each comprise one or plural semiconductor layers. The n-type semiconductor region and the p-type semiconductor region can furthermore also contain undoped layers. The semiconductor layers of the semiconductor layer sequence 2 include a nitride compound semiconductor material, in particular InₓAl_{y}Ga_{1-x-y}N, with 0≤x≤1, 0≤y≤1 and x+y≤1.

The active layer 4 can in particular be a radiation-emitting layer. More specifically, the active layer 4 can comprise a pn junction, preferably a single or multiple quantum well structure. For example, the nitride semiconductor component 10 is an optoelectronic component such as a light-emitting diode or a semiconductor laser. Alternatively, the active layer 4 can be a radiation-receiving layer and the optoelectronic semiconductor component can be a detector.

The lattice mismatch between the growth substrate 1 and the semiconductor layer sequence 2 may give rise to crystal defects occurring in the semiconductor layer sequence 2 during epitaxial growth, which defects can in particular be a result of mechanical stresses. One example of such crystal defects are threading dislocations 6, part of which propagate in the semiconductor layer sequence 2 essentially in parallel to the growth direction, i.e. perpendicularly to the growth substrate 1—as is shown schematically in FIG. 1. Another quantity of these threading dislocations only penetrate a portion of the semiconductor layer sequence 2, more specifically this quantity of the dislocations mostly do not penetrate most of the active layer 4. Where the threading dislocations 6 encounter a boundary surface 5A of a semiconductor layer 5, the semiconductor material will not grow parallel to the growth direction, but will form crystal facets 71 there that extend obliquely relative to the growth direction. As a result, recesses 7 can be formed at the end points of the threading dislocations 6 at the boundary surface 5A of the semiconductor layer 5, which recesses 7 can in particular be V-shaped in cross-section. The side facets 71 of the recesses 7 are (1-101) crystal surfaces or (11-22) crystal surfaces, for example.

Contrary to the simplified view of FIG. 1, the recesses at the boundary surface 5A of the semiconductor layer 5 can have different sizes that are randomly distributed, for example. Preferably, at least some of the recesses 7 have a lateral extent of at least 10 nm, more preferably of between 15 nm and 500 nm, and most preferably of between 20 nm and 300 nm. The depth of the recesses is preferably at least 10 nm, more preferably between 15 nm and 500 nm, most preferably between 20 nm and 500 nm.

In an embodiment of the method, the recesses 7 can be enlarged, as shown in FIG. 2. In particular, an etching process can be used for this purpose.

FIG. 3 is a schematic perspective view of one of the recesses 7. The essentially V-shaped recesses 7 can in particular have the shape of an inverted pyramid. The base area of the pyramid arranged at the boundary surface 5A of the semiconductor layer sequence can in particular be hexagonal, with the side facets 71 being typically formed by (1-101) crystal surfaces or (11-22) crystal surfaces.

In the method, a p-doped contact layer is applied to the boundary surface 5A of the semiconductor layer 5 having the V-shaped recesses 7, which contact layer—similar to the underlying layer of the semiconductor layer sequence 2—preferably comprises a nitride semiconductor material, in particular InₓAl_{y}Ga_{1-x-y}N, with 0≤x≤1, 0≤y≤1 and x+y≤1. In particular, the p-doped contact layer can be doped with magnesium.

FIGS. 4a) to 4c) are schematic views illustrating the application of the p-doped contact layer 8 to a portion of the boundary surface 5A which has a V-shaped recess 7. As is shown in FIG. 4a), the recess 7 is formed at a threading dislocation. The view of FIG. 4b) shows the initial stage of growth of a p-doped contact layer 8 that is grown on the boundary surface 5A of the semiconductor layer 5. The recess 7 is filled at least partially during growth of the p-doped contact layer 8. In this process, first regions 81 of the p-doped semiconductor layer 8 are created in the area of the recess 7, which regions 81 have a lower dopant concentration than second regions 82 that are arranged next to the recesses 7 in the lateral direction. In particular, it has turned out that—as the nitride semiconductor material grows on the oblique side facets 71 of the recesses 7—a lower dopant concentration is incorporated in the semiconductor material than in the second regions 82 in which the surface of the semiconductor material extends perpendicularly to the growth direction.

As the p-doped contact layer 8 is grown, the recesses 7 can be filled partially, as shown in FIG. 4b), or preferably completely, as shown in FIG. 4c). Preferably, growth of the p-doped contact layer 8 is interrupted when the recesses 7 are just about filled with the more lightly doped first regions 81.

Once the recesses 7 have been filled with the material of the p-doped contact layer 8, another planar growth surface has been created, with the result that the dopant concentration evens out again as the p-doped contact layer 8 continues to grow in the lateral direction. As shown in FIG. 5a), the more lightly doped first regions 81 can increasingly decrease in the growth direction, for example. As growth of the p-doped contact layer 8 proceeds, as shown in FIG. 5b), a more even dopant concentration is increasingly obtained in the p-doped contact layer 8 with increasing distance from the recesses until it is essentially constant in the lateral direction.

In order to achieve a dopant concentration at the surface of the p-doped contact layer 8 that varies in the lateral direction, the p-doped contact layer 8 is at least partially removed in one embodiment, as shown in FIG. 5c). For this purpose, an etching process is performed, for example. The p-doped contact layer 8 is thinned out in an etching process to such an extent that the more lightly doped first regions 81 will be exposed at the surface, for example.

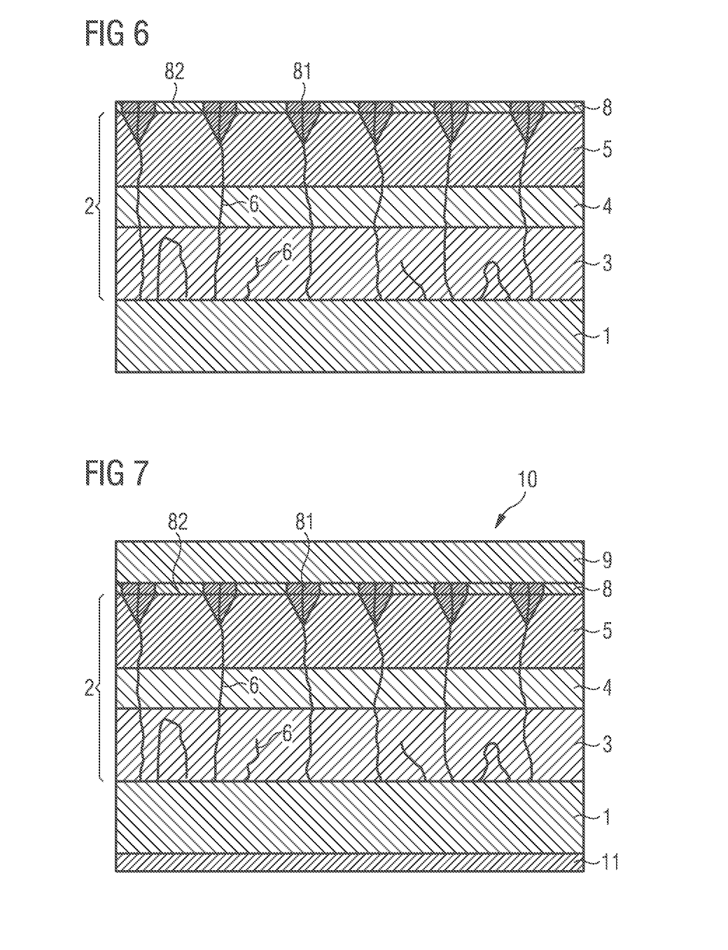

FIG. 6 is a view of an intermediate step in the production of the nitride semiconductor component in which the p-doped contact layer 8 has been grown on the boundary surface of the semiconductor layer 5. The p-doped contact layer 8 has a lower dopant concentration in first regions 81 which are arranged in the recesses or which adjoin the recesses in the vertical direction, than in second regions 82 that are arranged outside of the recesses, in particular offset from the recesses in the lateral direction. As has been explained with reference to FIG. 5, this can be achieved by interrupting the growth of the p-doped contact layer 8 before a constant dopant concentration is obtained in the lateral direction, or by removing the p-doped contact layer 8 after growth to such an extent that the first regions 81 of lower dopant concentration will be exposed at the surface of the p-doped contact layer 8.

In the first embodiment, illustrated in FIG. 7, of a nitride semiconductor component 10, a connection layer 9 has been deposited on the p-doped contact layer 8 in another step. The connection layer 9 serves to establish electrical contact for supplying electrical current to the semiconductor layer sequence 2. A second connection layer 11 can be arranged at the rear side of the growth substrate 1, for example, if the growth substrate 1 is an electrically conductive substrate. If an electrically insulating growth substrate has been chosen for the nitride semiconductor component 10, part of the semiconductor layer sequence 2 can be removed down to the n-doped semiconductor region 3, for example, where the second connection layer (not shown) can then be positioned.

The connection layer 9 is preferably a layer of a transparent conductive oxide, for example ITO or ZnO. A connection layer 9 made of a transparent conductive oxide is especially advantageous if the nitride semiconductor component is an optoelectronic component such as a light-emitting diode, in which radiation is outcoupled through the connection layer 9. In this case, the connection layer 9 can be advantageously applied to the entire connection layer 9 that results in good current expansion without any major absorption losses in the connection layer 9.

Alternatively, the connection layer 9 can be a layer made of a metal or a metal alloy, which in this case is applied preferably only to some areas of the connection layer 9. In the case of a connection layer 9 made of a metal or a metal alloy, the connection layer 9 can contain or consist of aluminum or silver, for example.

The first regions 81 of the p-doped contact layer 8 that adjoin the threading dislocations 6 have a lower dopant concentration than the second regions 82 that are spaced from the threading dislocations 6 in the lateral direction. This ensures that less current will be injected into the regions of the semiconductor layer sequence 2 that have the threading dislocations 6, than into the other regions of the semiconductor layer sequence 2. This reduces non-radiating recombinations of charge carriers in the area of the threading dislocations 6 that in turn increases the efficiency of the nitride semiconductor component 10.

FIG. 8 is a view of a portion of the p-doped contact layer 8 that adjoins one of the recesses. The recesses that are filled by the more lightly doped regions 81 of the contact layer 8 have an average width b. The ratio of a thickness a of the p-doped contact layer 8 to the averaged width b of the recesses advantageously satisfies the following conditions: a≤2*b, preferably a≤1.5*b, more preferably a≤0.5*b. Preferably, the p-doped contact layer is of a thickness of no more than 300 nm.

In yet another possible embodiment that is illustrated in FIG. 9, the p-doped contact layer 8 has a first partial layer that comprises the first regions 81 and the second regions 82. In the first partial layer, the dopant concentration varies in the lateral direction, similar to the embodiments described above, and it is in particular lower in the first regions 81 than in the second regions 82. On a side facing away from the semiconductor layer 5, a second partial layer 83 adjoins the first partial layer 81, 82, which second partial layer 83 has a dopant concentration which is higher than the dopant concentration of the first regions 81 and second regions 82 of the first partial layer. In this case, the second partial layer 83 with the higher dopant concentration advantageously has a thickness of c≤50 nm, preferably of c≤30 nm, and more preferably of c≤15 nm.

An important factor for the contact resistance between the p-doped contact layer 8 and a subsequent connection layer that includes a metal or a conductive oxide, for example, is not only the doping concentration at the intermediate boundary layer but also the doping concentration within a certain region of the p-contact layer. This region can be of a thickness of up to approx. 30 nm. In other words, the contact resistance between the p-doped contact layer 8 and the subsequent connection layer is co-determined by the last 30 nm of the p-contact layer 8. As long as the thickness c of the second partial layer 83 is not too high, i.e. c≤50 nm, preferably c≤30 nm, more preferably c≤15 nm, the contact resistance is higher in the area of the recesses than in other areas that are located between the recesses. This will therefore reduce the current flow in the area of the recesses.

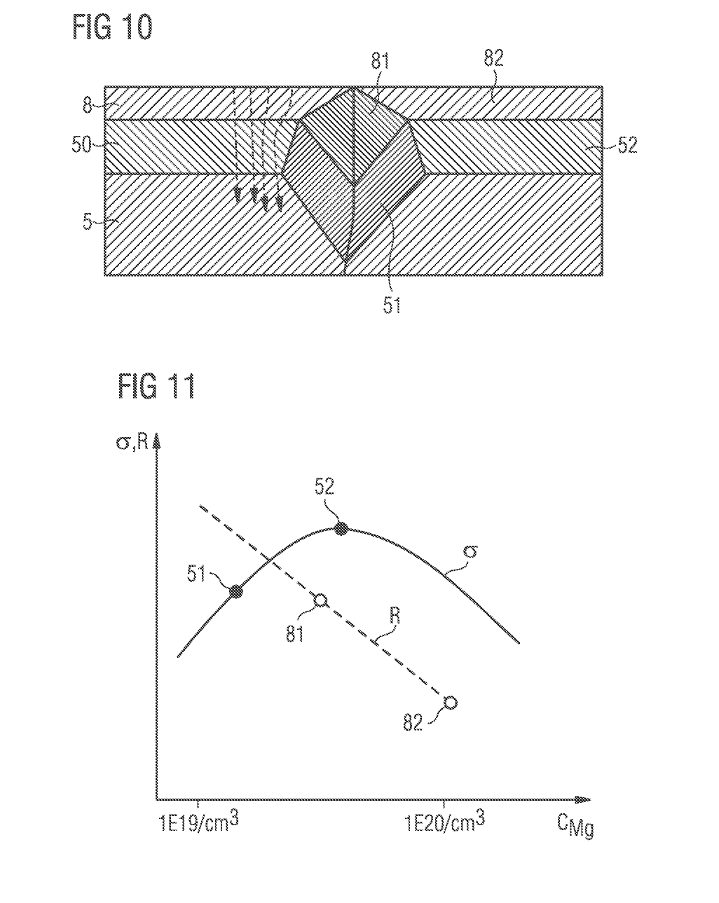

FIG. 10 is a view of another embodiment in which an additional semiconductor layer 50 is arranged between the semiconductor layer 5, in which the recesses are formed, and the p-doped contact layer 8. The additional semiconductor layer 50 is advantageously also of the p-doped type and has a lower dopant concentration than the p-doped contact layer 8. The additional semiconductor layer 50 in particular has a lower dopant concentration than the second partial regions 82 of the p-doped contact layer 8. The dopant concentration in the additional semiconductor layer 50 is preferably lower than 1*10²⁰/cm³, more preferably lower than 8*10¹⁹/cm³, most preferably lower than 6*10¹⁹/cm³. Similar to the p-doped contact layer 8 that has first regions 81 with a lower doping concentration in the area of the recesses and second regions 82 of a higher doping concentration, the additional semiconductor layer 50 also has first regions 51 with a lower doping concentration in the area of the recesses and second regions 52 with a higher doping concentration.

This embodiment is based on the insight, amongst others, that the p-conductivity in the nitride compound semiconductor system does not increase monotonically with increasing dopant content, but decreases again from approx. 4*10¹⁹/cm³ onwards. For example, a layer having a dopant concentration of 1*10²⁰/cm³ can have a poorer p-conductivity than a layer having a dopant concentration of 4*10¹⁹/cm³. However, this relationship is not true for the contact resistance. The contact resistance decreases with increasing dopant concentration, even if the dopant concentration is more than 4*10¹⁹/cm³. As a result, the highly doped second partial areas 82 of the p-doped contact layer can have a low contact resistance but poor conductivity, whereas the partial areas 81 of the lower doping concentration can have a high contact resistance but good conductivity.

FIG. 11 is a schematic graph illustrating the relationship between the p-dopant concentration c_{Mg} of magnesium, for example, the conductivity σ and the contact resistance R (in arbitrary units). Also indicated as examples are the conductivity of the first regions 51 and of the second regions 52 of the additional semiconductor layer 50, as well as the contact resistance of the first regions 81 and of the second regions 82 of the p-doped contact layer 8. The second partial regions 82 have a higher doping concentration than the first partial regions 81, with the result that the contact resistance R is smaller in the second partial regions 82 and thus current preferably flows in these regions. The second partial regions 52 of the additional semiconductor layer 50 have a higher doping concentration than the first partial regions 51 and thus higher conductivity σ, with the result that current preferably flows in the second partial regions 52, as is schematically indicated by arrows in FIG. 10. This advantageously reduces the flow of current in the area of the recesses, i.e. in the area of threading dislocations.

Another embodiment similar to the embodiment of FIG. 10 is shown in FIG. 12. Similar to the embodiment of FIG. 10, this embodiment has an additional semiconductor layer 50 underneath the p-doped contact layer 8, which additional semiconductor layer 50 has a lower dopant concentration than the second partial areas 82 of the p-doped contact layer 8. However, the additional semiconductor layer 50 of the embodiment shown here does not necessarily have different partial areas of varying doping concentrations.

The additional semiconductor layer 50 preferably has a thickness d which—compared to the mean thickness e of the recesses—satisfies the following relationship: d>0.1*e, preferably d>0.25*e, more preferably d>0.5*e. It follows from this geometrical relationship between the additional semiconductor layer 50 of relatively good conductivity and the depth of the recesses that current increasingly flows from the second partial regions 82 to the additional semiconductor layer 50, instead of from the second partial areas 82 to the first partial areas 81 of the p-doped contact layer 8. This keeps charge carriers away from the dislocation and thus reduces losses.

The further embodiment of a nitride semiconductor component 10 illustrated in FIG. 13 is a so-called thin-film LED in which the semiconductor layer sequence 2 has been removed from its original growth substrate. The original growth substrate has been removed from the n-doped region 3 that, in this embodiment, is arranged at the radiation exit surface 12 of the optoelectronic nitride semiconductor component 10. On the side opposite the original growth substrate, the semiconductor component has been applied to a carrier 14, for example by means of a connection layer 13 such as a layer of solder. As seen from the active layer 4, the p-doped contact layer 8 thus faces the carrier 14. The carrier 14 can include silicon, germanium or a ceramic, for example.

As in the embodiment described above, the p-doped contact layer 8 contains first regions 81 that adjoin threading dislocations 6 in the semiconductor layer sequence 2 and have a lower dopant concentration than the second regions 82. The p-doped contact layer 8 with the first regions 81 and the second regions 82 adjoins the connection layer 9 that advantageously contains a metal or a metal alloy. The formation of the differently doped regions 81, 82 of the p-doped contact layer 8 and the resulting advantages are the same here as in the first embodiment and will thus not be explained again.

In addition to its function as an electrical contact layer, the connection layer 9 can in particular serve as a mirror layer for reflecting the radiation emitted by the active layer 4 in the direction of the carrier 14 towards the radiation output surface 12. The reflecting connection layer 9 can in particular contain or consist of silver or aluminum. For producing a second electrical connection, a second connection layer 11 can be deposited on the n-doped semiconductor region 3. As an alternative to the illustrated example of arranging the second connection layer 11 at the radiation exit surface 12, the n-doped semiconductor region 3 can be contacted by means of vias, for example, which are introduced into the n-doped semiconductor region 3 from the side of the carrier 14.

It is possible to arrange one or plural additional layer(s) (not shown) between the reflecting connection layer 9 and the solder layer 13 which connects the semiconductor component to the carrier 14. In particular, these may be a bonding layer, a wetting layer and/or a barrier layer, which is to prevent the material of the solder layer 13 from diffusing into the reflecting connection layer 9.

The invention is not restricted by the description given with reference to the exemplary embodiments. Rather, the invention encompasses any novel feature and any combination of features, in particular any combination of features in the claims, even if this feature or this combination is not itself explicitly indicated in the claims or exemplary embodiments.

### LIST OF REFERENCE NUMBERS

1 growth substrate
2 semiconductor layer sequence
3 n-doped semiconductor layer
4 active layer
5 p-doped semiconductor layer
5A boundary surface
6 threading dislocation
7 V-shaped recess
8 p-doped contact layer
9 connection layer
10 nitride semiconductor component
11 second connection layer
12 radiation exit surface
13 connection layer
14 carrier
50 additional semiconductor layer
51 first regions
52 second regions
71 side facets
81 first regions
82 second regions

1. Method for producing a nitride semiconductor component, comprising the following steps:
epitaxially growing a nitride semiconductor layer sequence on a growth substrate, wherein recesses are formed at a boundary surface of a semiconductor layer of the semiconductor layer sequence,
growing a p-doped contact layer over the semiconductor layer, wherein the p-doped contact layer at least partially fills the recesses, and wherein the p-doped contact layer has a lower dopant concentration in first regions arranged at least partially in the recesses than in second regions arranged outside of the recesses, and
applying a connection layer, which comprises a metal, a metal alloy, or a transparent conductive oxide, to the p-doped contact layer.

2. Method according to claim 1, wherein the dopant concentration in the p-doped contact layer varies in the lateral direction at a boundary surface to the connection layer.

3. Method according to claim 1, wherein growing the p-doped contact layer is interrupted before a dopant concentration is obtained at a growth surface that is constant in the lateral direction.

4. Method according to claim 1, wherein the p-doped contact layer has a thickness a, and the recesses have an average lateral extent b, and wherein a≤2*b.

5. Method according to claim 1, wherein part of the p-doped contact layer is removed at least partially after being grown.

6. Method according to claim 1, wherein, before growing the p-doped contact layer, an etching process is performed to produce and/or enlarge the recesses at the boundary surface of the semiconductor layer.

7. Method according to claim 1, wherein at least part of the recesses are at least 10 nm wide.

8. Method according to claim 1, wherein at least part of the recesses are at least 10 nm deep.

9. Method according to claim 1, wherein the dopant concentration in the second regions is at least 5*10¹⁹ cm⁻³.

10. Method according to claim 1, wherein the dopant concentration in the second regions is partially at least 1.5 times as high as in the first regions.

11. Method according to claim 1, wherein the p-doped contact layer includes a first partial layer containing the first regions and the second regions, and a second partial layer, which second partial layer has a higher dopant concentration than the first regions and the second regions.

12. Method according to claim 1, wherein, before growing the p-doped contact layer, an additional semiconductor layer is grown on the semiconductor layer, and wherein the additional semiconductor layer has a lower dopant concentration than the second regions of the p-doped contact layer.

13. Method according to claim 12, wherein the additional semiconductor layer has a thickness d and the recesses have an average depth e, and wherein d>0.1*e.

14. Nitride semiconductor component, comprising
a nitride semiconductor layer sequence, with
recesses being formed at a boundary surface of a semiconductor layer of the semiconductor layer sequence,
a p-doped contact layer which at least partially fills the recesses, wherein the p-doped contact layer has a lower dopant concentration in first regions which are at least partially arranged in the recesses than in second regions arranged outside of the recesses, and
a connection layer made of a metal, a metal alloy or a transparent conductive oxide which follows the p-doped contact layer.

15. Nitride semiconductor component according to claim 14, wherein the dopant concentration in the p-doped contact layer varies in the lateral direction at a boundary surface to the connection layer.

16. Nitride semiconductor component according to claim 14, wherein the dopant concentration in the second regions is at least partially 1.5 times as high as in the first regions.

17. Nitride semiconductor component according to claim 14, wherein the nitride semiconductor component is an optoelectronic component, wherein the semiconductor layer sequence includes an n-type semiconductor region, a p-type semiconductor region and an active layer arranged between the n-type semiconductor region and the p-type semiconductor region, and wherein the p-type semiconductor region comprises at least the semiconductor layer and the p-doped contact layer.

18. Method for producing a nitride semiconductor component, comprising the following steps:
epitaxially growing a nitride semiconductor layer sequence on a growth substrate, wherein recesses are formed at a boundary surface of a semiconductor layer of the semiconductor layer sequence,
growing a p-doped contact layer over the semiconductor layer, wherein the p-doped contact layer at least partially fills the recesses, and wherein the p-doped contact layer has a lower dopant concentration in first regions arranged at least partially in the recesses than in second regions arranged outside of the recesses, and
applying a connection layer, which comprises a metal, a metal alloy, or a transparent conductive oxide, to the p-doped contact layer,
wherein the dopant concentration in the p-doped contact layer varies in the lateral direction at a boundary surface to the connection layer.
